(19) United States
(12) Patent Application Publication
(10) Pub. No.: US 2014/0373889 A1
(43) Pub. Date: Dec. 25, 2014

(54) TE PERFORMANCE BY BAND CONVERGENCE IN (Bi1-XSbX)2Te3

(71) Applicant: California Institute of Technology, Pasadena, CA (US)

(72) Inventors: G. Jeffrey Snyder, Pasadena, CA (US); Hyun-sik Kim, Pasadena, CA (US)

(73) Assignee: California Institute of Technology, Pasadena, CA (US)

(21) Appl. No.: 14/309,815

(22) Filed: Jun. 19, 2014

Related U.S. Application Data
(60) Provisional application No. 61/837,052, filed on Jun. 19, 2013.

(51) Int. Cl. H01L 35/16; H01L 35/28; H01L 35/18

(52) U.S. Cl. CPC H01L 35/16; H01L 35/18; H01L 35/28
USPC 136/203; 252/62.3 T; 423/508; 136/205

(57) ABSTRACT

Disclosed herein are thermoelectric materials with high performance characteristics, and methods of use thereof Among the thermoelectric materials disclosed are those of the formula (Bi₁₋ₓSbₓ)₂Te₃. In some embodiments, the invention teaches that 0.5≦x≦0.9. In some embodiments, the invention further teaches doping with iodine (I), in order to decrease the hole carrier concentration of (Bi₁₋ₓSbₓ)₂Te₃ mixed crystal and improve zT.

### CROSS REFERENCE TO RELATED APPLICATION

This application claims priority under 35 U.S.C. §119(e) from U.S. Provisional Application No. 61/837,052 filed Jun. 19, 2013, which is hereby incorporated by reference in its entirety.

### FIELD OF THE INVENTION

The instant disclosure generally relates to materials with high thermoelectric performance, and methods of manufacturing and using the same.

### BACKGROUND

Thermoelectric applications, including both power generation utilizing the Seebeck effect and refrigeration utilizing the Peltier effect, have attracted increasing interest worldwide in the past decade. For example, thermoelectric devices are being rapidly developed for waste heat recovery applications, particularly in automobiles, to produce electricity and reduce carbon emissions. The development of efficient thermoelectric devices for both space and terrestrial applications can benefit from the availability of compositions that have a high thermoelectric figure of merit (zT).

### SUMMARY OF THE INVENTION

In various embodiments, the invention teaches an article of manufacture that includes (Bi₁₋ₓSbₓ)₂Te₃, wherein 0.5≦x≦0.9. In some embodiments, x is 0.75. In some embodiments, the article includes a quantity of iodine (I) as a dopant. In certain embodiments, 0.1 at. %≦I≦0.6 at. %. In some embodiments, the article of manufacture has a zT≧1 at 300K. In some embodiments, the hole carrier concentration is 1.2×10¹⁹ (cm⁻³).

In various embodiments, the invention teaches a method that includes using an article of manufacture in a thermoelectric device, wherein the article of manufacture includes (Bi₁₋ₓSbₓ)₂Te₃, and wherein 0.5≦x≦0.9. In some embodiments, x is 0.75. In some embodiments, the article of manufacture used in conjunction with the inventive method includes a quantity of iodine (I) as a dopant. In some embodiments, 0.1 at. %≦I≦0.6 at. In various embodiments, the article of manufacture used in conjunction with the inventive method has a zT≧1 at 300K. In certain embodiments, the hole carrier concentration of the article of manufacture is 1.2×10¹⁹ (cm⁻³).

In some embodiments, the inventive method includes applying a temperature gradient to the article of manufacture, and collecting electrical energy.

In certain embodiments, the inventive method includes applying electrical energy to the article of manufacture, and transferring heat from a first space at a first operation temperature to a second space at a second operation temperature, wherein the first operation temperature is lower than the second operation temperature.

### BRIEF DESCRIPTION OF THE DRAWINGS

Exemplary embodiments are illustrated in the referenced figures. It is intended that the embodiments and figures disclosed herein are to be considered illustrative rather than restrictive.

FIG. 1 demonstrates, in accordance with an embodiment of the invention, a graph showing total density of state effective mass versus composition, x, acquired by applying a single parabolic band model to literature data (left). Based on the total density of state effective mass versus composition graph, a schematic diagram for a valence structure in (Bi₁₋ₓSbₓ)₂Te₃ for 0≦x≦1 was constructed (right).

FIG. 2 demonstrates, in accordance with an embodiment of the invention, for (Bi₁₋ₓSbₓ)₂Te₃, for 0≦x≦1 mixed crystal there are two valence bands V_{I} and V₂ that participate in transport. The band masses of V₁ and V₂ stay the same as x changes (left). A schematic representation of a proposed valence structure of (Bi₁₋ₓSbₓ)₂Te₃ for 0≦x≦1 is shown on the right.

FIG. 3 demonstrates, in accordance with an embodiment of the invention, a graph of Seebeck versus hole carrier concentration showing literature data, a single band model and a two band model. Both the single band model and the two band model describe the literature data closely.

FIG. 4 demonstrates, in accordance with an embodiment of the invention, a graph of hole mobility versus hole carrier concentration. When hole mobility versus hole carrier concentration is considered, the two band model describes the literature data more accurately than the single band model.

FIG. 5 demonstrates, in accordance with an embodiment of the invention, the state of the art material has a hole carrier concentration of 3.8×10¹⁹ (cm⁻³) (empty dark gray star). it was anticipated that if the carrier concentration is tuned to 1.2×10¹⁹ (cm⁻³), the zT value at 300 (K) would improve by more than 20%.

FIG. 6 demonstrates, in accordance with an embodiment of the invention, the concentration of iodine at the Te site in terms of the at. % of iodine doped in Sb₂Te₃.

### DESCRIPTION OF THE INVENTION

All references cited herein are incorporated by reference in their entirety as though fully set forth. Unless defined otherwise, technical and scientific terms used herein have the same meaning as commonly understood by one of ordinary skill in the art to which this invention belongs.

In some embodiments, the numbers expressing quantities of ingredients, properties such as molecular weight, reaction conditions, and so forth, used to describe and claim certain embodiments of the application, are to be understood as being modified in some instances by the term “about,” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

By way of additional background, thermoelectric (FE) applications have attracted increasing interest worldwide in the last decade as a means of combatting the ever growing rate of energy consumption. The two main applications for thermoelectric materials are power generation, which utilizes the Seebeck effect, and solid state cooling, which has its roots in the Peltier effect. Recently, power generation has been of prime interest to the automotive industry as a sustainable and emission free waste heat recovery process. Discussion about this can be found at, for example, L. E. Bell, Science (2008), 321, 1457, which is hereby incorporated by reference in its entirety as though fully set forth. The effectiveness of this process is restricted by the overall efficiency of the thermoelectric materials.

A common figure of merit for a thermoelectric material, denoted by z, is defined as z=S²σ/(κ_{E}+κ_{L}), where S is the Seebeck coefficient, σ is the electrical conductivity, and κ_{E} and κ_{L} are the electronic (or carrier) component and phonon (or lattice) component of the thermal conductivity, respectively. The Seebeck coefficient S for a thermoelectric material is the voltage difference per degree Kelvin. The electrical conductivity σ is inverse of the electrical resistivity^{,} ρ. The figure of merit z has the units of reciprocal Kelvin. Another figure of merit, which is referred to as thermoelectric figure of merit, can be defined as zT, where T is the absolute temperature in Kelvin, so that zT is a dimensionless quantity.

As demonstrated herein, the inventors have developed improved thermoelectric materials. In various embodiments, the invention teaches an article of manufacture that includes (Bi₁₋ₓSbₓ)₂Te₃. In certain embodiments, x is at least 0.1, or at least 0.2, or at least 0.3, or at least 0.4, or at least 0,5, or at least 0.6, or at least 0.7, or at least 0.8, or at least 0.9, In some embodiments, 0.1≦x≦0.9. In some embodiments, 0.2≦x≦0.8. In some embodiments, 0.3≦x≦0.7. In certain embodiments, x is 0.75. In various embodiments, iodine (I) is used to dope the article of manufacture at the Te site. In some embodiments, iodine (I) can be used to dope from at least 0.01 at. %, or at least 0.02 at. %, or at least 0.03 at. %, or at least 0.04 at. %, or at least 0.05 at. %, or at least 0.06 at. %, or at least 0.07 at. %, or at least 0.08 at. %, or at least 0.09 at. %, or at least 0.1 at. %, or at least 0.2 at. %, or at least 0.3 at. or at least 0.4 at. %, or at least 0.5 at. %, or at least 0.6 at. %_{;} or at least 0.7 at. %, or at least 0.8 at. %, or at least 0,9 at. %, or at least 1.0 at. %, In some embodiments, 0.1 at. %≦I≦0.6 at. %. In some embodiments, the article of manufacture has a hole carrier concentration of at least 10¹⁸ per cubic centimeter, or at least 2×10¹⁸ per cubic centimeter, or at least 4×10¹⁸ per cubic centimeter, or at least 5×10¹⁸ per cubic centimeter, or at least 6×10¹⁸ per cubic centimeter, or at least 8×10¹⁸ per cubic centimeter, or at least 10¹⁹ per cubic centimeter, or at least 2×10′⁹ per cubic centimeter, or at least 4×10¹⁹ per cubic centimeter, or at least 5×10¹⁹ per cubic centimeter. Merely by way of example, a preferred hole carrier concentration is 1.0×10¹⁹ to 2.0×10¹⁹ per cubic centimeter. In some embodiments, the article of manufacture has a hole carrier concentration of 1.2×10¹⁹ per cubic centimeter. In some embodiments, the article of manufacture has a zT≧1 at 300K. In some embodiments, the article of manufacture has a zT of about 1.6 at a temperature range of 250-350 K.

In various embodiments, the invention teaches a method that includes using an article of manufacture in a thermoelectric device, wherein the article of manufacture includes (Bi₁₋ₓSbₓ)₂Te₃. In certain embodiments, x is at least 0.1, or at least 0.2, or at least 0.3, or at least 0.4, or at least 0.5, or at least 0.6, or at least 0.7, or at least 0.8, or at least 0.9. In some embodiments, 0.1≦x≦0.9. In some embodiments, 0.2≦x≦0.8. In some embodiments, 0.3≦x≦0.7. In certain embodiments, x is 0.75. In various embodiments, iodine (I) is used to dope the article of manufacture at the Te site In some embodiments, iodine (I) can be used to dope from at least 0.01 at. %, or at least 0.02 at. %, or at least 0.03 at. %, or at least 0.04 at. or at least 0.05 at. %, or at least 0.06 at. %, or at least 0.07 at. %, or at least 0.08 at. %, or at least 0.09 at. %, or at least 0.1 at. %, or at least 0.2 at. %, or at least 0.3 at. %, or at least 0.4 at. %, or at least 0.5 at. %, or at least 0.6 at. %, or at least 0.7 at. %, or at least 0.8 at. %, or at least 0.9 at. %, or at least 1.0 at. %. In some embodiments, 0.1 at. %≦I≦0.6 at. %. In some embodiments, the article of manufacture used in conjunction with the inventive method has a hole carrier concentration of at least 10¹⁸ per cubic centimeter, or at least 2×10¹⁸ per cubic centimeter, or at least 4×10¹⁸ per cubic centimeter, or at least 5×10¹⁸ per cubic centimeter, or at least 6×10¹⁸ per cubic centimeter, or at least 8×10¹⁸ per cubic centimeter, or at least 10¹⁹ per cubic centimeter, or at least 2×10¹⁹ per cubic centimeter, or at least 4×10¹⁹ per cubic centimeter, or at least 5×10¹⁹ per cubic centimeter. Merely by way of example, a preferred hole carrier concentration is 1.0×10¹⁹ to 2.0×10¹⁹ per cubic centimeter, Ire some embodiments, the article of manufacture has a hole carrier concentration of 1.2×10¹⁹ per cubic centimeter. In some embodiments, the article of manufacture used in conjunction with the inventive method has a zT≧1 at 300K. in some embodiments, the article of manufacture has a zT of about 1.6 at a temperature range of 250-350 K.

In some embodiments, the method of using an article of manufacture described above includes applying a temperature gradient to the article of manufacture, and collecting electrical energy. In some embodiments, the method includes applying electrical energy to the article of manufacture, and transferring heat from a first space at a first operation temperature to a second space at a second operation temperature, wherein the first operation temperature is lower than the second operation temperature.

Some embodiments of the instant disclosure are directed to a method of manufacturing an article, In various embodiments, the method includes using elemental bismuth, antimony, and tellurium, and optionally the compound bismuth iodide or antimony iodide. The initial elements are placed in an evacuated quartz ampoule and sealed under a pressure of approximately 10⁻⁵ Torr. The ampoule is then placed in a furnace at 900° C. and held at this temperature for 12 hours. After melting, the material is ground in an argon atmosphere into a powder. The resulting powder is then placed into a new quartz ampoule and then vacuum sealed once more at a pressure of 10⁻⁵ Torr The material is then melted once again at a temperature of 900° C. for a time duration of 10 minutes. The resulting ingot is approximately 60-80 mm in length with a diameter of 6 mm.

The final previously described ampoule is then placed in a zone melting furnace in which the bottom of the ingot is initially melted, with a typical zone length of ˜10 mm. The temperature is held at approximately 650° C. The growth rate is typically 2.7 mm/hr and the zone melting lasts ˜24 hours. The technique of zone melting is used to grow oriented polycrystalline materials that are used in the characterization of the transport properties.

The following examples are for illustrative purposes only and are not intended to limit the scope of the disclosure or its various embodiments in any way.

### EXAMPLES

The following examples are included to demonstrate embodiments disclosed herein. It would be appreciated by those of skill in the art that the methodology and compositions disclosed in the examples which follow represent methodology discovered by the inventors to function well in the practice of the disclosure, and thus can be considered to constitute particular modes tier its practice. However, those of skill in the art would, in light of the present disclosure, appreciate that many changes can be made to the specific embodiments disclosed while still obtaining a like or similar result, and without departing from the spirit and scope of the disclosure.

### Example 1

### Introduction

In 1981, Gaidukova and Erofeev showed that there was an abrupt peak in total density of state effective mass at x=0.75 by using a simple one-band model. A similar result was also obtained by Stordeur in 1988 with his optical spectroscopy and transport calculations where he assumed that the band degeneracy is constant (Nᵥ=6). Because it is believed that the band degeneracies of a valence band and its sub-valence band of Bi₂Te₃ and Sb₂Te₃ are six for both materials, assuming the band degeneracy to be six for 0≦x≦1 in (Bi₁₋ₓSbₓ)₂Te₃ is the same as postulating that only a single valence band participates in transport phenomena.

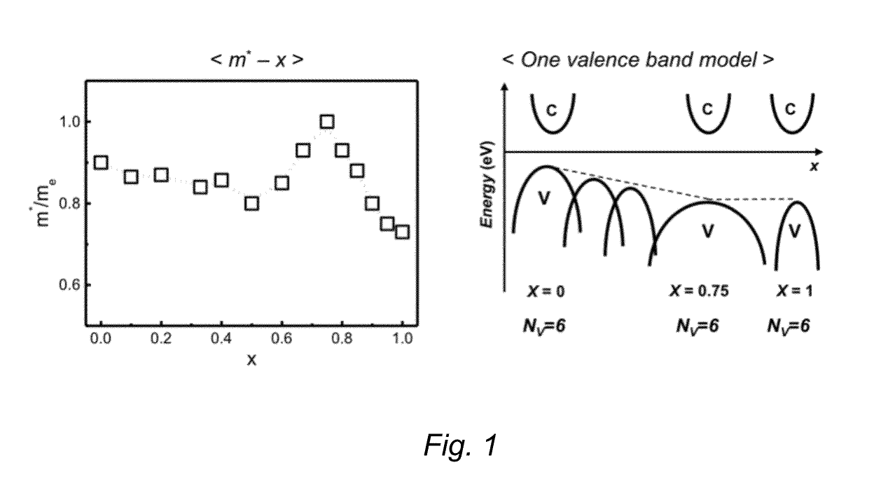

The inventors acquired a total density of state effective mass versus composition, x, as shown in the left of FIG. 1, by applying a single parabolic band model to literature data. Based on the total density of state effective mass versus composition graph, a schematic diagram for a valence structure in (Bi₁₋ₓSbₓ)₂Te₃ for 0≦x≦1 was constructed, as shown in the right of FIG. 1.

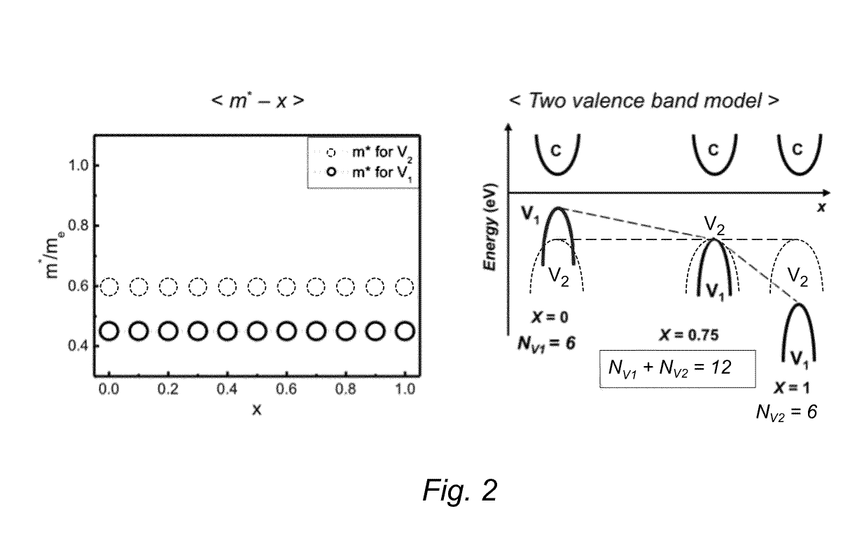

The inventors wanted to find a physical mechanism behind the abrupt broadening of the valence band at x=0.75. It was determined that for (Bi₁₋ₓSbₓ)₂Te₃ (0≦x≦1) mixed crystal there are two valence bands V₁ and V₂ that participate in transport. The band masses of V₁ and V₂ stay the same as x changes (as shown in the left of FIG. 2). The band mass of V₁ is smaller than V₂. Energy of the valence band V₁ decreases as x increases. For x=0, the band mass of the sub-valence band is higher than that of the valence band. For x=1, the band mass of the valence band is higher than that of the subvalence band. Energy of the valence band V₂ stays the same as x increases. The two valence bands converge at x=0.75. The band degeneracy at x=0.75 is 12 (band degeneracies of the two valence bands V₁ and V₂ are both six). While not wishing to be bound by any one particular theory, it appears very likely that the valence structure of (Bi₁₋ₓSbₓ)₂Te₃ for 0≦x≦1 can be schematically presented as shown in the right of FIG. 2.

### Example 2

### Two Valence Bands Versus One Valence Band

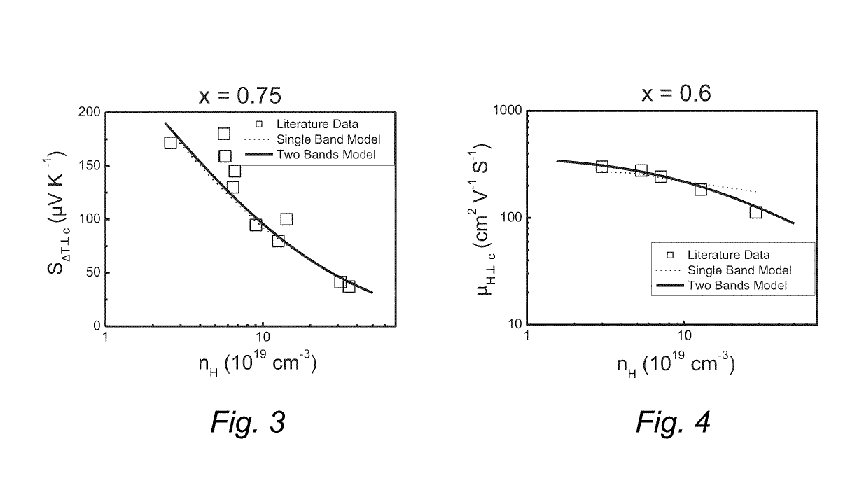

Although in the Seebeck versus hole carrier concentration graph both the single band model and the two band model describe the literature data closely (FIG. 3), when hole mobility versus hole carrier concentration is considered the two band model describes the literature data more accurately than the single band model (FIG. 4).

### Example 3

### zT Prediction by the Two Band Model

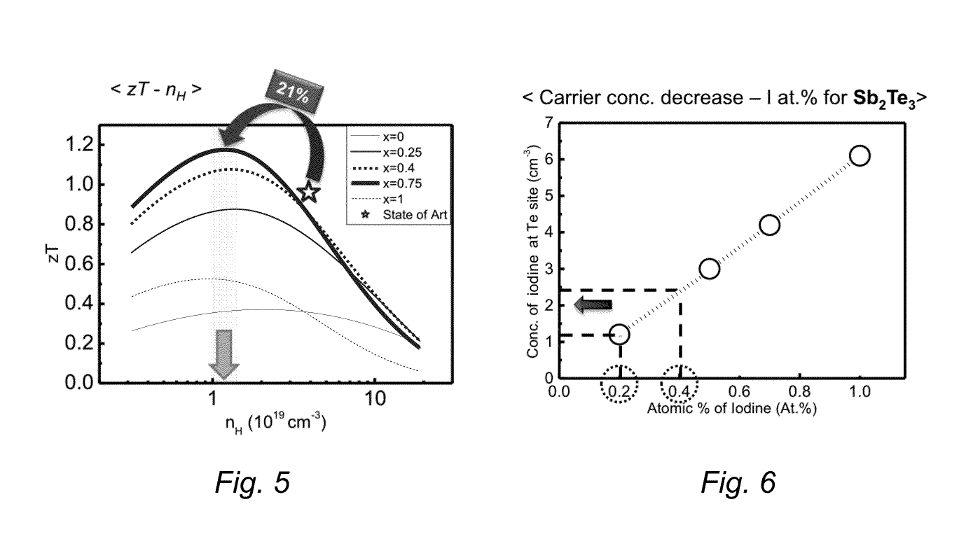

Using the two band model, the inventors predicted that for the composition x=0.75, (Bi_{0.25}Sb_{0.75})₂Te₃, a hole carrier concentration of 1.2×10¹⁹ (cm⁻³) will result in the highest zT value at 300 (K). Since the state of the art material has a hole carrier concentration of 3.8×10¹⁹ (cm⁻³) (empty dark gray star in FIG. 5), if the carrier concentration is tuned to 1.2×10¹⁹ (cm^{31 3}), the zT value at 300 (K) is expected to improve by more than 20%.

### Example 4

### Exemplary Compositions and Doping

In some preferred embodiments, (Bi₁₋ₓSbₓ)₂Te₃ mixed crystal articles of manufacture range from 0.5≦x≦0.9. This range of compositions corresponds to that of the abrupt increase in the total density of state effective mass in terms of composition in the left of FIG. 1. FIG. 6 shows the concentration of iodine at the Te site in terms of at. % of iodine doped in Sb₂Te₃. In certain preferred embodiments of the inventive compositions described herein, Iodine can be doped from 0.1 at. % to 0.6 at. % to decrease the hole carrier concentration of (Bi₁₋ₓSbₓ)₂Te₃ mixed crystal, thereby improving zT.

The various methods and techniques described above provide a number of ways to carry out the application. Of course, it is to be understood that not necessarily all objectives or advantages described can be achieved in accordance with any particular embodiment described herein. Thus, for example, those skilled in the art will recognize that the methods can be performed in a manner that achieves or optimizes one advantage or group of advantages as taught herein without necessarily achieving other objectives or advantages as taught or suggested. herein. A variety of alternatives are mentioned herein. It is to be understood that some preferred embodiments specifically include one, another, or several features, while others specifically exclude one, another, or several features, while still others mitigate a particular feature by inclusion of one, another, or several advantageous features.

Furthermore, the skilled artisan will recognize the applicability of various features from different embodiments. Similarly, the various elements, features and steps discussed above, as well as other known equivalents for each such element, feature or step, can be employed in various combinations by one of ordinary skill in this art to perform methods in accordance with the principles described herein. Among the various elements, features, and steps some will be specifically included and others specifically excluded in diverse embodiments.

Although the application has been disclosed in the context of certain embodiments and examples, it will be understood by those skilled in the art that the embodiments of the application extend beyond the specifically disclosed embodiments to other alternative embodiments and/or uses and modifications and equivalents thereof.

In some embodiments, the terms “a” and “an” and “the” and similar references used in the context of describing a particular embodiment of the application (especially in the context of certain of the following claims) can be construed to cover both the singular and the plural. The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (for example, “such as”) provided with respect to certain embodiments herein is intended merely to better illuminate the application and does not pose a limitation on the scope of the application otherwise claimed. No language in the specification should be construed as indicating any non-claimed element essential to the practice of the application.

Preferred embodiments of this application are described herein, including the best mode known to the inventors for carrying out the application. Variations on those preferred embodiments will become apparent to those of ordinary skill in the art upon reading the foregoing description. it is contemplated that skilled artisans can employ such variations as appropriate, and the application can be practiced otherwise than specifically described herein. Accordingly, many embodiments of this application include all modifications and equivalents of the subject matter recited in the claims appended hereto as permitted by applicable law. Moreover, any combination of the above-described elements in all possible variations thereof is encompassed by the application unless otherwise indicated herein or otherwise clearly contradicted by context.

All patents, patent applications, publications of patent applications, and other material, such as articles, books, specifications, publications, documents, things, and/or the like, referenced herein are hereby incorporated herein by this reference in their entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that can be employed can be within the scope of the application. Thus, by way of example, but not of limitation, alternative configurations of the embodiments of the application can be utilized in accordance with the teachings herein. Accordingly, embodiments of the present application are not limited to that precisely as shown and described.

What is claimed is:

1. An article of manufacture comprising (Bi₁₋ₓSbₓ)₂Te₃, wherein 0.5≦x≦0.9.

2. The article of manufacture of claim 1, wherein x is 0.75.

3. The article of manufacture of claim 1, comprising a quantity of iodine (I) as a dopant

4. The article of manufacture of claim 3, wherein 0.1 at. %≦I≦0.6 at. %.

5. The article of manufacture of claim 4, wherein zT≧1 at 300K.

6. The article of manufacture of claim 4, wherein the hole carrier concentration is 1.2×10¹⁹ (cm⁻³).

7. A method comprising using an article of manufacture in a thermoelectric device, wherein the article of manufacture comprises (Bi₁₋ₓSbₓ)₂Te₃, and wherein 0.5≦x≦0.9.

8. The method of claim 7, wherein x is 0.75.

9. The method of claim 7, wherein the article of manufacture comprises a quantity of iodine (I) as a dopant.

10. The method of claim 9, wherein 0.1 at. %≦I≦0.6 at. %.

11. The method of claim 10, wherein the article of manufacture has a zT≧1 at 300K.

12. The method of claim 10, wherein the hole carrier concentration of the article of manufacture is 1.2×10¹⁹ (cm⁻³).

13. The method of any of claims 7-12, comprising:
applying a temperature gradient to the article of manufacture; and
collecting electrical energy.

14. The method of any of claims 7-12, comprising:
applying electrical energy to the article of manufacture; and
transferring heat from a first space at a first operation temperature to a second space at a second operation temperature, wherein the first operation temperature is lower than the second operation temperature.
